(19) United States
(12) Patent Application Publication
(10) Pub. No.: US 2012/0234581 A1
(43) Pub. Date: Sep. 20, 2012

(54) Percolative Conductive Network and Conductive Polymer Composite

(76) Inventors: Ilia N. Ivanov, Knoxville, TN (US); Matthew P. Garrett, Sandston, VA (US); Rosario A. Gerhardt, Marietta, GA (US); John M. Boyea, Decatur, GA (US)

(21) Appl. No.: 13/051,503

(22) Filed: Mar. 18, 2011

(51) Int. Cl. H05K 1/03; H01B 1/22; H05K 1/09; H01B 1/24; B82Y 99/00

(52) U.S. Cl. 174/255; 174/257; 252/511; 252/506; 977/932; 977/742

(57) ABSTRACT

A percolative conductive network includes bundles of carbon nanotubes and clusters of conductive particles arranged on a substrate. A plurality of the bundles include one or more points of contact with at least one adjacent bundle to form a carbon nanotube network, and the clusters of conductive particles separate the bundles in regions between the points of contact. At least a portion of the clusters form conductive pathways between adjacent bundles, and the carbon nanotube network and the conductive pathways define a percolative conductive network on the substrate.

### FEDERALLY SPONSORED RESEARCH OR DEVELOPMENT

This invention described in this disclosure was made with government support under Prime Contract Number DE-AC05-00OR22725 awarded by the Department of Energy. The government has certain rights in this invention.

### TECHNICAL FIELD

The present disclosure is directed generally to transparent conductive composites and more particularly to conductive composites based on carbon nanotubes and conductive particles.

### BACKGROUND

Transparent conductors have become widely used in a variety of applications, including solar cells, liquid crystal and other flat panel displays, light-emitting diodes, and electrochromic and smart windows. A transparent conductor typically includes a transparent and electrically conductive film deposited on a transparent substrate, such as glass or a polymer.

Conductive metal oxides, such as tin-doped indium oxide, which is commonly known as indium-tin oxide (ITO), may be deposited in the form of a transparent coating on various substrates using conventional physical or chemical vapor deposition methods, such sputtering. ITO is the current standard for transparent conductive coatings. Thin films of ITO exhibit a low-resistivity (e.g., 1-3×10⁻⁴ Ωcm) and high optical transparency (>85%) in the visible wavelength region. However, indium-tin oxide films may be limited in mechanical durability, and the vacuum deposition methods and equipment employed for fabrication may be expensive and energy-intensive. In addition, the world-wide supply of indium is rapidly depleting and the price of indium is increasing accordingly.

Carbon nanotube (CNT)-based coatings have been investigated as an alternative to ITO for forming conductive coatings. A carbon nanotube is a cylindrical arrangement of carbon atoms generally having the form of a graphene sheet that has been rolled into a cylinder. Carbon nanotubes were first discovered in 1991 by an NEC researcher in Japan and since then have been found to have enhanced physical and electronic properties compared to conventional carbon fibers and other materials. The diameter of individual carbon nanotubes, which may be single-wall or multi-wall structures, is typically in the range of single nanometers.

Carbon nanotubes can be deposited in thin layers on a wide range of substrates and maintain their conductive properties under flexing. Also, while ITO has become more expensive, nanotubes have dropped in price as methods of manufacture and purification have improved. However, the transparency of CNT coatings, which are typically formed from a random assembly of nanotubes, may not be sufficient for all applications. The resistance and transparency of a number of CNT-based coatings, as reported in the scientific literature, are shown in FIG. 1.

The data point indicated by a star shows the properties of a coating formed from ITO, which is considered to be the current state-of-the-art transparent conductive coating material. As can be seen, the resistance of the CNT coatings increases at higher transmittance levels and is substantially higher than the resistance of ITO at the same transparency. For use in a flat panel display, a transparent conductive coating may require a transmittance (T) of least 80% and a resistance of under 200 Ω/Sq. For a touch screen monitor, the coating may require a resistance under 1000 Ω/Sq and over 90% T, and an organic LED may need at least 90% T at a resistance under 10 Ω/Sq.

To meet the appropriate conductivity requirements at the necessary transmittance, improvements in the nanotube assemblies that form the basis of such films are needed. It would be advantageous to devise a low-cost method to fabricate a transparent conductive coating that exhibits both a low resistance and a high optical transparency.

### BRIEF SUMMARY

A percolative conductive network that includes carbon nanotubes and clusters of conductive particles, and a conductive polymer composite are described herein. The network and the composite are designed to provide a desirable combination of electrical conductivity and optical transmittance.

The percolative conductive network includes bundles of carbon nanotubes and clusters of conductive particles arranged on a substrate. A plurality of the bundles include one or more points of contact with at least one adjacent bundle to form a carbon nanotube network, and the clusters of conductive particles separate the bundles in regions between the points of contact. At least a portion of the clusters form conductive pathways between adjacent bundles, and the carbon nanotube network and the conductive pathways define a percolative conductive network on the substrate.

The conductive polymer composite includes bundles of carbon nanotubes and clusters of conductive particles dispersed in a polymer matrix. A plurality of the bundles include one or more points of contact with at least one adjacent bundle to form a carbon nanotube network through the polymer matrix, and the clusters of conductive particles separate the bundles of carbon nanotubes in regions between the points of contact. At least a portion of the clusters form conductive pathways between adjacent bundles, and the carbon nanotube network and the conductive pathways define a percolative conductive network through the polymer matrix.

### BRIEF DESCRIPTION OF THE DRAWINGS

FIG. 1 shows a plot of resistance (Ω/Sq) as a function of % transmittance at 550 nm using data from the scientific literature;

FIG. 2 is a schematic of an exemplary conductive network including carbon nanotubes and clusters of conductive particles dispersed on a substrate;

FIG. 3 is a scanning electron microscope (SEM) image of a carbon nanotube network;

FIG. 4 is a schematic of an exemplary composite including carbon nanotubes and clusters of conductive particles dispersed in a polymer matrix;

FIG. 5 is a photograph showing an exemplary polymer composite formed from a compressed mixture of polystyrene beads, multiwall carbon nanotubes (MWNTs) and indium-tin oxide (ITO) particles;

FIG. 6A shows resistivity as a function of MWNT content for exemplary ITO-MWNT powders exposed to different compression pressures;

FIG. 6B shows % transmittance as a function of wavelength for two exemplary polymer composites including different loading levels of ITO particles and MWNTs;

FIG. 7 is a schematic of a carbon nanotube-conductive particle (e.g., ITO particle) architecture and an equivalent circuit model;

FIG. 8 is an scanning electron micrograph showing a doped nanotube network including bundles and junctions;

FIGS. 9A and 9B show and absorbance data for exemplary transparent conductive coatings composed of doped nanotubes;

FIG. 10 shows resistance as a function of transmittance (quality factor) for exemplary transparent conductive coatings composed of doped nanotubes;

FIG. 11 shows a progressive reduction in the bundle and junction resistance for an exemplary doped carbon nanotube network as a function of dopant and compared to an undoped nanotube network;

FIG. 12 shows the change in quality factor as a function of transmittance for exemplary transparent conductive coatings incorporating doped nanotubes;

FIG. 13 shows how the percolation threshold of a conductive nanotube network depends on the geometry (e.g., diameter and length) of the nanotubes, which may be idealized as rods; and

FIG. 14 shows how the percolation threshold of a conductive nanotube network depends on the aspect ratio and alignment of the nanotubes, which are again idealized as rods.

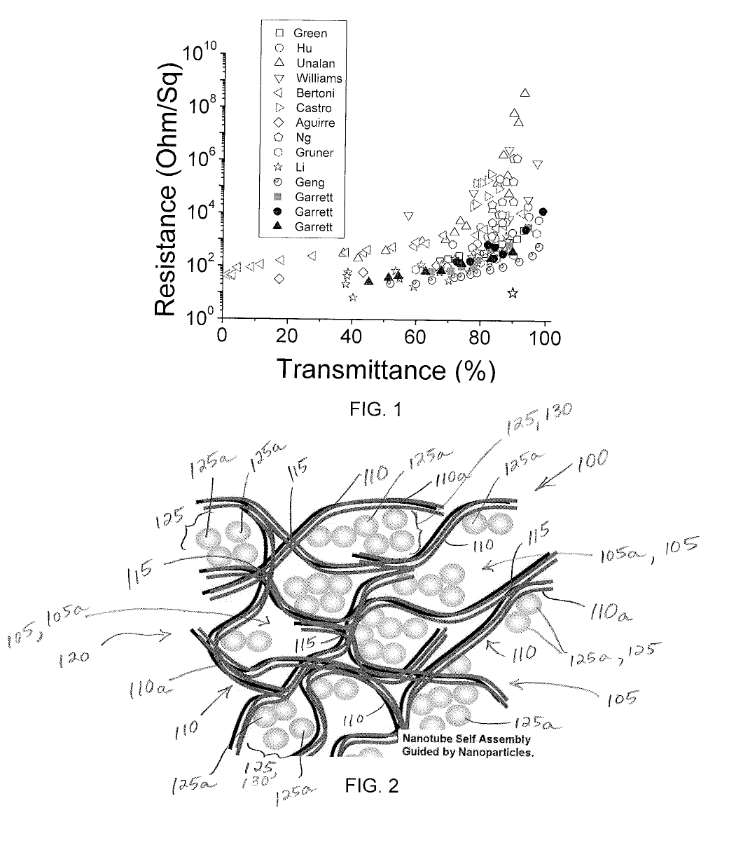

### DETAILED DESCRIPTION

The excellent conductivity of carbon nanotubes and the conductivity and transparency obtainable from conductive particles such ITO are exploited to form a percolative conductive network and a polymer composite that exhibit high electrical conductivity without sacrificing optical transmittance.

Referring to FIG. 2, the percolative conductive network 100 includes bundles 110 of carbon nanotubes 110a and clusters 125 of conductive particles 125a arranged on a substrate 105. A plurality of the bundles 110 include one or more points of contact (or intersections or junctions) 115 with at least one adjacent bundle 110 to form a carbon nanotube network 120. Advantageously, a majority of the bundles 110 include the one or more points of contact 115. In addition, clusters 125 of conductive particles 125a separate the bundles 110 of carbon nanotubes 110a in regions 105a between the points of contact 115, where at least a portion of the clusters 125 form conductive pathways 130 between adjacent bundles 110. The carbon nanotube network 120 and the conductive pathways 130 define a percolative conductive network 100 on the substrate 105, which is typically made of a transparent material such as glass or a polymer.

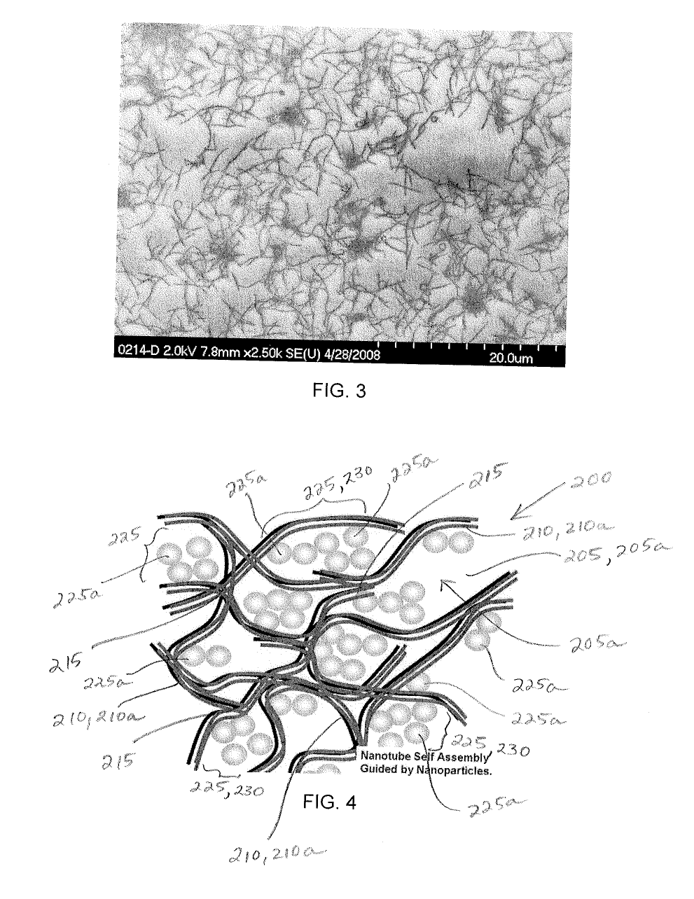

A percolative conductive network can be defined as an arrangement of conducting structures (in this case, carbon nanotubes and clusters of conductive particles) that are sufficient to yield a continuous conductive pathway. In the examples here, the conductive pathway is formed on a substrate or through another medium, such as a polymer matrix. Such a network may be said to have reached or exceeded a percolation threshold, which is the minimum concentration of the conducting material(s) needed to assemble the conductive pathway: below this threshold the network is not conductive, while above it, the network is conductive. In the case of carbon nanotubes alone, for example, when initially deposited on a substrate, there may be an insufficient number density of nanotubes to form a continuous network. That is, the network may have an infinite resistance on a macroscopic scale. As one continues to deposit nanotubes on the substrate, a critical loading may be reached where there are sufficient points of contact between adjacent nanotubes to form a continuous network and create a conductive pathway across the substrate. This critical loading amount is the percolation threshold. As more nanotubes are added, the conductivity may continue to increase along with the density of nanotubes in the network. Additionally, the transparency of such carbon nanotube networks diminishes with higher nanotube loading levels, as discussed previously. FIG. 3 is a scanning electron micrograph (SEM) of a single wall carbon nanotube (SWNT) network just above the percolation threshold. A continuous network is shown, but removal of only a few nanotubes could leave isolated clusters of non-percolative nanotubes.

In the present disclosure, conductive particles are employed along with carbon nanotubes to form a conductive percolative network, thereby enhancing both the conductivity and the transparency of the network. By including the conductive particles, the percolation threshold may be reached at a lower carbon nanotube concentration than achievable with carbon nanotubes alone, and/or a higher conductivity may be achieved at the same carbon nanotube loading level. When dispersed with a random arrangement of carbon nanotubes, the conductive particles tend to form clusters that serve to separate the carbon nanotubes into the bundles shown in FIG. 2. Since the conductive clusters (e.g., indium-tin oxide nanoparticle clusters) may exhibit better transparency than randomly arranged carbon nanotubes, a conductive network including carbon nanotubes separated into bundles with clusters of conductive particles dispersed in between may show a significantly improved transparency than a network formed from carbon nanotubes alone. In addition, at least some of the clusters form conductive pathways between adjacent nanotubes, as mentioned above.

The percolative conductive network may exhibit a transmittance (T) of at least about 50% at a specified wavelength (e.g., 550 nm) between about 390 nm and about 750 nm, and the transmittance T may also be at least about 60%, at least about 70%, at least about 80%, or at least about 90% at the specified wavelength. Transmittance is defined as the fraction (percentage) of incident light at a specified wavelength that passes through a sample. The resistance (Ω/sq) of the percolative conductive network is advantageously about 200 Ω/sq or less, preferably at a transmittance of at least about 80% at the specified wavelength.

The onset of percolation in a network is dependent on the length-to-width aspect ratio of the conductive materials that comprise up the network, as discussed in greater detail below. The greater the aspect ratio, the lower the percolation threshold. Advantageously, the carbon nanotube bundles employed in the conductive percolative networks described here typically have a length-to-width aspect ratio of from about 100 to about 1000 or even greater. The bundles preferably include carbon nanotubes with a similar longitudinal alignment and a close spacing. The bundles may include about 10 carbon nanotubes or less, where each carbon nanotube has an average diameter of in the range of about 1 nm to about 50 nm and an average length in the range of about 50 nm to about 10 microns.

The bundles may be formed during processing of a random arrangement of carbon nanotubes when conductive particles are added to the mixture. The conductive particles tend to cluster together by Van der Waals forces and thus, at an appropriate loading level, may facilitate separation of the carbon nanotubes into the above-described bundles. The particles may have a negligible length-to-width aspect ratio (that is, an aspect ratio of close to 1) and an average size which is on the nanoscale, similar to the width of the carbon nanotubes. For example, the average size of the conductive particles may lie between about 1 to 50 nm, where the average particle size corresponds to an average diameter in the case of substantially spherical particles. The conductive particles may therefore be referred to as conductive nanoparticles.

Typically, the weight ratio of carbon nanotubes to conductive particles in the percolative conductive network may lie between about 1:1 and about 1:10. The carbon nanotubes may be single wall or multiwall carbon nanotubes, or a mixture of both. Such nanotubes may be synthesized using methods known to one of ordinary skill in the art, or they may be obtained from commercial sources.

The conductive particles may be formed of one or more conductive materials, which may be metals, alloys, and/or conductive oxides. The conductive material may include, for example, one or more metallic elements selected from among Ti, V, Cr, Mn, Fe, Co, Ni, Cu, Zn, Zr, Nb, Mo, Ru, Rh, Pd, Ag, Cd, Hf, Ta, W, Re, Os, Ir, Pt, Au, Al, In, Sn, Pb, and Bi. Advantageously, the conductive material may include indium-tin oxide (ITO), zinc oxide (highly n-type doped with F, Al, Ga or In) or other conductive oxides. Such conductive particles may be produced by vapor phase or solution phase synthesis methods known in the art, or the particles may be obtained from commercial sources. By interdispersing clusters of such conductive particles between bundles of carbon nanotubes, a desirable combination of conductivity and transparency may be achieved from the network.

The carbon nanotubes may also include a dopant for enhanced conductivity. The dopant may be incorporated through covalent or non-covalent interactions and may result in the reduction of a potential energy barrier for charge carrier transport through the conductive network. Experimental data discussed below indicate that in carbon nanotube-based transparent conductive coatings, both the junction and carbon nanotube bundle resistance are changed (reduced) by doping. A similar effect is expected for networks of carbon nanotubes and conductive particles; a suitable dopant may reduce the resistance of nanotube-nanotube junctions, nanotube bundles, conductive particle junctions, and conductive particle-nanotube junctions. Dopants that may be suitable include thionyl chloride and ortho-dichlorobenzene and others. The dopant may be applied to the carbon nanotubes by dipping in an appropriate solution prior to mixing the nanotubes with the conductive particles, as described below or by chemical modification of the nanotubes.

FIG. 4 shows a conductive composite 200 includes a polymer matrix 205, and bundles 210 of carbon nanotubes 210a dispersed in the polymer matrix 205. A plurality of the bundles 210 include one or more points of contact (or intersections or junctions) 215 with at least one adjacent bundle 210 to form a carbon nanotube network 220 through the matrix 205. Additionally, clusters 225 of conductive particles 225a separate the bundles 210 in regions 205a between the points of contact 215, and at least a portion of the clusters 225 form conductive pathways 230 between adjacent bundles 210. Together, the carbon nanotube network 220 and the conductive pathways 230 define a percolative conductive network 235 through the polymer matrix.

The carbon nanotubes 210a and the conductive particles 225a dispersed in the polymer matrix 205 may include the characteristics (e.g., aspect ratio, average size) described above. The carbon nanotubes may be present in the polymer matrix at a concentration of between about 0.001 wt. % and about 10 wt. %, and the conductive particles may be present in the polymer matrix at a concentration of between about 0.001 and 20 wt. %; accordingly, the weight ratio of carbon nanotubes to conductive particles in the polymer matrix may lie between about 2,000:1 and about 1:2,000.

The polymer(s) employed to form the polymer matrix may contribute to the conductivity of the composite, or the polymer matrix may be formed from one or more dielectric polymers that do not significantly enhance the conductivity of the network. In the former case, a lower loading level of carbon nanotubes and/or conductive particles may be needed to reach the percolation threshold. For example, the polymer(s) may be selected from among polystyrene, polycarbonate, and poly-methyl methacrylate. In one embodiment, as discussed further below in Example 1, the polymer matrix may be formed from compressed polystyrene beads and the carbon nanotube network and clusters of conductive particles may be localized at interfaces between adjacent compressed beads.

The transparent conductive composite may exhibit a transmittance (T) of at least about 50% at a specified wavelength (e.g., 550 nm) between about 390 nm and about 750 nm, and the transmittance T may also be at least about 60%, at least about 70%, at least about 80%, or at least about 90% at the specified wavelength. As stated previously, transmittance is defined as the fraction (percentage) of incident light at a specified wavelength that passes through a sample. The resistance (Ω/sq) of the transparent conductive composite is advantageously about 200 Ω/sq or less, preferably at a transmittance of at least about 80% at the specified wavelength.

### EXAMPLE 1

### ITO-CNT Transparent Conductive Composites

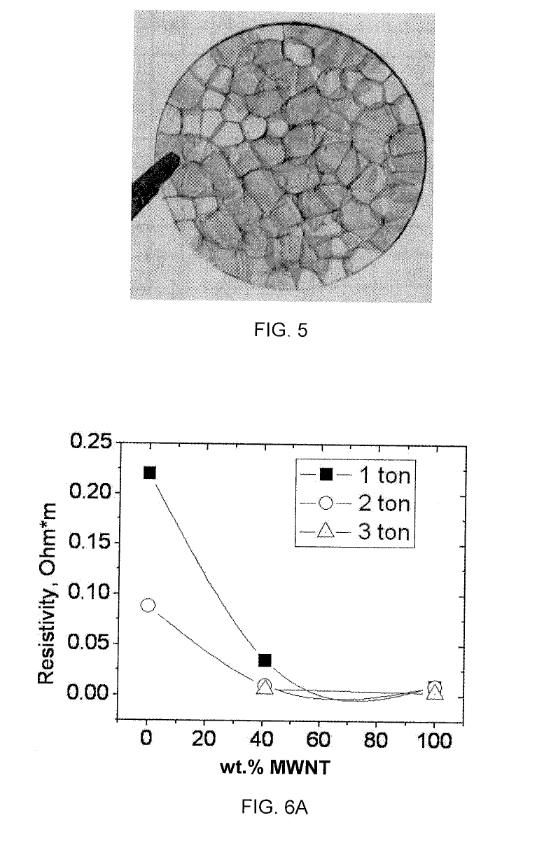

Commercially available multiwall carbon nanotubes were mixed with ITO powders in different proportions and added to polystyrene beads to create 5 mm diameter and 1 mm thick polymer composites, as shown for example in FIG. 5. The composites were made by compression of components under 1 ton, 2 ton, and 3 ton conditions. The ITO particles and the MWNTs are believed to be localized at interfaces between the compressed beads of polystyrene.

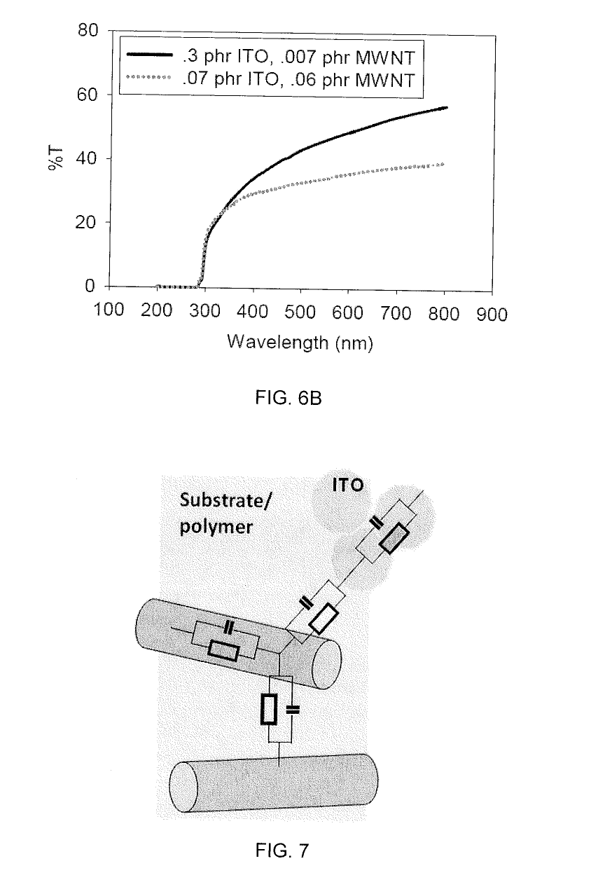

Without any carbon nanotubes (0 wt. %), the ITO nanoparticles showed improved conductivity at higher levels of compression, as shown in FIG. 6A, which is a plot of resistivity (Ω·m) versus loading level of multiwall carbon nanotubes (wt. % MWNT). Reducing the interfacial contact resistance is a key to higher conductivity. As the loading level of MWNTs increased from 0 wt. % to 20 wt. %, the resistivity drops by as much as a factor of five, where the decrease is more significant at the 1 ton compression level than at the 2 ton compression level. At carbon nanotube loading levels above about 40 wt. % MWNT, the resistivity of the composite does not show a significant change. The conductivity of the ITO-MWNT-composite at a 40 wt. % MWNT loading level is similar to that for a 100%. Furthermore, the presence of the ITO nanoparticles serves to improve the transparency of the polymer composite (compared to the same composite with carbon nanotubes alone) without reducing the conductivity of the composite. Referring to the data shown in FIG. 6B, the two samples have the same resistance (1 MΩ), whereas the sample that includes 0.3 parts per hundred resin(phr) ITO and 0.007 phr MWNT shows a much higher % transmittance than the sample that includes only 0.07 phr ITO and 0.06 phr MWNT.

In addition, at an appropriate loading level of ITO nanoparticles, the conductivity of the transparent conductive composite may be improved due to the clustering of the ITO particles and the formation of additional conducting paths between adjacent bundles of carbon nanotubes. It may also be possible to improve the conductivity of the transparent conductive composite by using high purity single wall carbon nanotubes (SWNTs) in place of some or all of the MWNTs, as SWNTs may have a higher electrical conductivity than MWNTs.

### EXAMPLE 2

### Influence of Doping on Properties of Composites

Doping of the carbon nanotubes with dopants obtained from solutions of nitric acid (HNO₃), dichlorosulfoxide (SOCl₂), and sulfuric acid (H₂SO₄) and ortho-dichlorobenzene (ODCB; C₆H₄Cl₂), for example, may provide another avenue to increase the conductivity of the polymer composites without diminishing the transmittance of optical light. The doping may be carried out by dipping the nanotubes into a solution containing the desired dopant prior to mixing the nanotubes with the conductive particles.

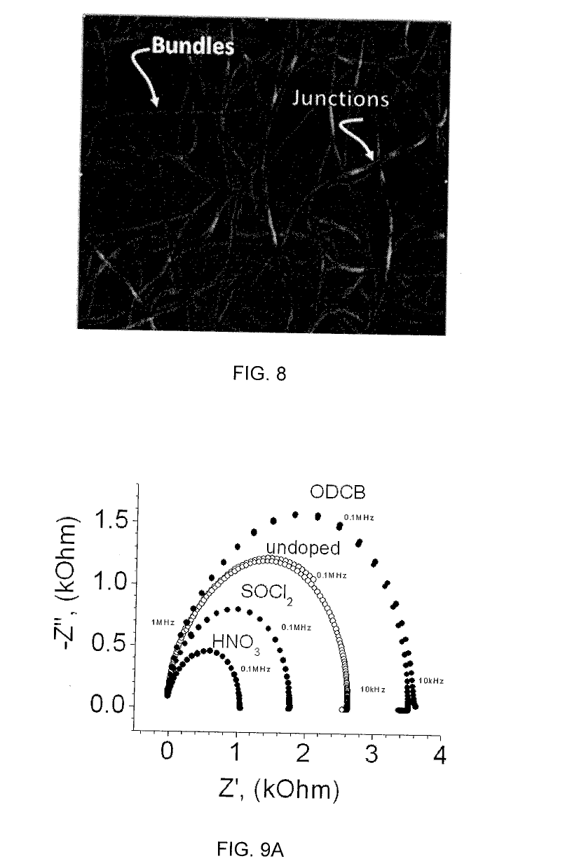

FIG. 7 provides a schematic of a doped carbon nanotube-conductive particle architecture and an equivalent circuit model, and FIG. 8 shows an electron micrograph of doped nanotubes, where bundles and junctions are identified. Nanotube networks include two major contributors to the electrical resistance, the nanotube bundle-to-nanotube bundle junction impedance and the nanotube bundle impedance itself. Doping has been shown to be effective in reducing both of these impedances.

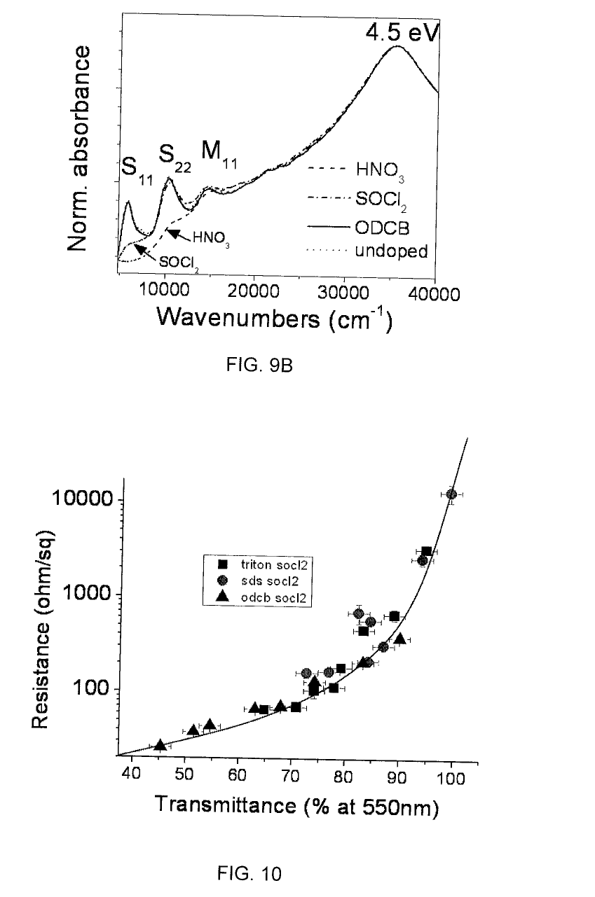

FIGS. 9A and 9B show that the impedance of the carbon nanotubes decreases with doping, while the transmittance of nanotube-based transparent conductive films remains largely unchanged. The dopant may remove residuals of surfactant, and/or reduce nanotube junction and bundle impedance, thereby improving the conductivity of the nanotubes and leading to transparent conductive films that have an improved quality factor. The quality factor may be defined to be the electrical resistance obtained at a given % transmittance for a transparent conductive coating or composite, and is preferably a low value. The quality factor for exemplary doped composites is shown in FIG. 10.

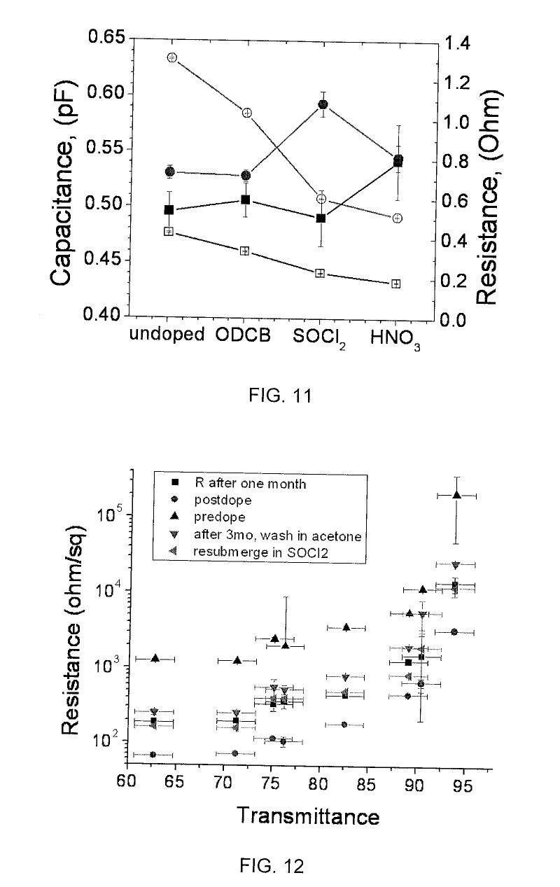

Statistically averaged values of junction and bundle resistance can be obtained through fitting experimental impedance traces (e.g., FIG. 9A) to the equivalent circuit model of the conductive network (e.g., FIG. 7). Modeling indicates that the dopant reduces the resistance of both bundles (R1) and junctions (R2), as shown in FIG. 11, which shows resistance and capacitance values for several doped nanotube networks and also an undoped nanotube network. The graph reveals a progressive reduction of R1 (□) and R2 (◯) as a function of dopant and compared to an undoped SWNT network. Capacitive equivalents of nanotube bundles and junctions remained fairly unchanged.

For some dopants, experiments have shown that the quality factor may worsen over time; that is, the resistivity of the specimen may increase at a given transmittance. For example, in the case of SOCl₂-doped carbon nanotubes, the data of FIG. 12 show that the quality factor is unstable from the time of doping (“postdope”) through one month and three months later. Accordingly, the stability of the dopant should be considered and may need to be improved.

### Theory: Percolation Behavior and the Percolation Threshold

Charge transport in polymer-embedded nanotube networks has been studied extensively, and models for percolation in these nanotube polymer networks have been proposed. Even at nanotube densities below percolation, the polymer matrix may still provide a current carrying capacity. Networks of only nanotubes differ in this regard, as there is no medium to transport charge once the nanotube density falls below the percolation threshold. Different methods are therefore necessary to experimentally determine percolation in these networks, since large-scale electrical properties cannot be studied below percolation threshold.

Due to a 1/3:2/3 metallic: semiconducting ratio of single wall carbon nanotubes, metallic tubes are expected to form a continuous network after the overall formation of the nanotube network. This is thought to be of importance, as the junctions between metallic tubes have better transport properties than junctions involving semiconducting tubes. A rise in conductivity would be expected once a continuous network of metallic tubes is formed. This metallic threshold has been determined to exist at around 80% T (where T is transmittance). However, continuous networks below the metallic threshold may be desirable for some applications. Therefore, a study of the “real” percolation threshold of a nanotube network is warranted. Of particular interest is inclusion of the semiconducting nanotubes at appropriate doping levels because the percolation threshold for semiconducting nanotubes is expected to be at transmittances >80 percent.

The onset of percolation in a network is dependent on the aspect ratio of the objects which comprise the network. If each carbon nanotube is idealized as a rod of length 2a and diameter 2b, then the percolation threshold is p_{c} ∝ b/a. Thus, the greater the aspect ratio, the lower the threshold.

As it is of interest to understand the role that junctions between bundles play in the networks in addition to the role of the SWNT bundles themselves, it is important to know how the number of intersections scales with the number of carbon nanotubes. Assuming all carbon nanotubes are idealized as rods as described above and that they are randomly oriented with respect to one another, and have a soft-core interaction, the average number of intersections per nanotube, N, is linearly proportional to the number of nanotubes, p: N=(4/π)(a/b)p. The percolation threshold, p_{c}, therefore corresponds to a critical number of intersections (or points of contact between adjacent nanotubes), N_{c}, where a continuous network forms on a large scale, p_{c}=(π/4)(b/a)N_{c}. The value of N_{c} is invariant, independent of aspect ratio, and has been found to be about 3.64 or one, depending on the author. The value is not invariant, however, when the size of the objects is widely distributed. The total number of intersections in the network, Nₜₒₜ, is quadratically dependent on the total number of nanotubes, and by algebra can be determined simply to be Nₜₒₜ=(4/π)(a/b)p².

A percolation network can be generally described as an array of sites, a lattice, where sites are either occupied or unoccupied. If two occupied sites are adjacent to one another, they are said to be connected, bound to one another. In the case of our idealized nanotube rods, a point where a nanotube exists can be considered to be an occupied site, and the intersection of two nanotubes can be considered to be bound sites. A network below the percolation threshold is composed of isolated bundles of nanotubes, and as p_{c} is approached, the bundles become interconnected until a continuous network of conductive nanotubes is formed. Eventually, far enough above p_{c}, there are no isolated bundles, and all of the nanotubes are connected. The strength of this network, that is, the probability that a given site belongs to the theoretically infinite network, scales in the form P ∝ (p−p_{c})β. Note that this scaling law is independent of the lattice; the shape and size of the objects and the number of dimensions occupied changes only the values of p_{c} and β, with the law retaining the same form.

Considering carbon nanotubes as rigid rods and applying the definition of percolation threshold for the 2D case in anisotropic systems it is possible to calculate the percolation threshold concentration of carbon nanotubes using an excluded volume concept:

For a percolation threshold concentration of SWNT (qₚ)

$${q}_{p} = \frac{{N}_{c}}{{V}_{p}} \approx \frac{1}{{V}_{ex}} \qquad ( 1 )$$

where N_{c} is the number of rods at percolation and Vₚ is the volume of the cube in which percolation problem is considered (in the case of a composite it is the composite volume), and Vₑₓ is the excluded volume, which could be expressed in terms of nanotube dimensions.

$${V}_{ex} ( d , l ) = 2 \cdot d \cdot ( \frac{2 \cdot π}{3} \cdot {d}^{2} + π \cdot d \cdot l + {l}^{2} \cdot 〈 sin γ 〉 ) \qquad ( 2 )$$

where d and l are the diameter and the length of an elementary unit of the conducting network: a single nanotube (or nanotube bundle), γ is the angle between possible orientation of two elementary conducting units of the network (for the isotropic case <sin γ>=π/4)

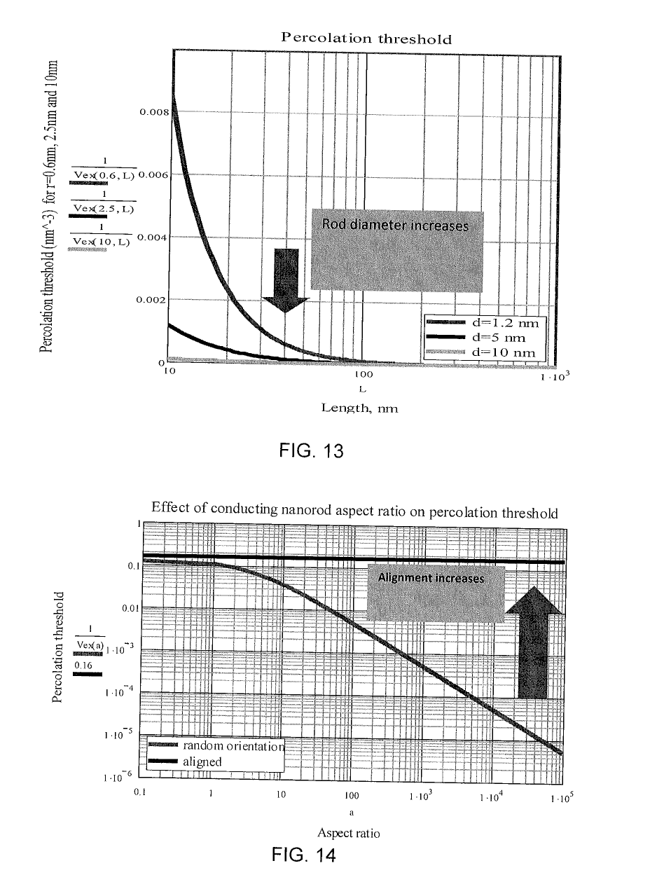

The percolation threshold was calculated for three diameters of conducting units (rods) 1 nm, 2 nm and 10 nm and increasing length of the unit from 1 nm to 10⁵ nm. Referring to FIG. 13, there are two distinct areas in the graph, one where the percolation threshold depends on both the diameter and length of conducting rods (for L<100 r) and another where the percolation threshold depends only on the diameter (for L>100 r).

For laser-synthesized nanotubes, this critical point can be estimated for two instances: 1) dispersed SWNT d=1.2-1.6 nm, r=0.6-0.7 nm, L=100 r=600-700 nm; 2) SWNT bundles d=20 nm, r=10 nm L=1000 nm=1 μm. For HIPCO SWNT characterized by large amount of catalyst, the values are d=0.8-1.2 nm, L<1 μm, and for Ressasco's SWNTs grown using MoCo catalyst technology, d=0.4-1.4 nm, L<1 μm.

Laser SWNTs are larger diameter, less defective, longer, and their diameter and length (aspect ratio) can be controlled by the nature of catalyst and processing conditions. Parameters of laser SWNTs are close to those produced by electrical arc process (arc-tubes), but the laser tubes are generally of higher quality (high ratio).

Of particular interest are double wall nanotubes (especially with d>1.4 nm, see aspect ratio considerations) including an inner and outer wall; such nanotubes can sacrifice the outer wall to enable better dispersion in solution while providing nearly defect free electrical conductivity through the inner wall. The double wall carbon nanotubes are expected to perform better than single wall carbon nanotubes in combination with conductive nanoparticles due to a drastically reduced number of side wall defects on the inner walls of the nanotubes.

FIG. 13 clearly indicates an advantage of large diameter conducting rods (for example, double wall carbon nanotubes) as they have a lower percolation threshold, especially if networks are built from shorter rods with L<100 r. These conditions may be written in terms of an aspect ratio of the rods: a=L/d<50, where the aspect ratio is defined as the ratio of the length of a rod to its diameter: a=L/d

The dependence of percolation threshold on the aspect ratio a of the conducting rods is shown in FIG. 14 for two extreme cases of completely aligned and randomly oriented conducting rods. It can be concluded that the percolation threshold is expected to be much lower for the random orientation than for completely aligned rods. FIGS. 13 and 14 indicate that use of longer conducting rods (e.g., carbon nanotubes) is beneficial for the design of a composite with a minimal amount of conducting rods.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein.

Furthermore, the advantages described above are not necessarily the only advantages of the invention, and it is not necessarily expected that all of the described advantages will be achieved with every embodiment of the invention.

1. A percolative conductive network comprising:
bundles of carbon nanotubes arranged on a substrate, a plurality of the bundles including one or more points of contact with at least one adjacent bundle to form a carbon nanotube network; and
clusters of conductive particles separating the bundles of carbon nanotubes in regions between the points of contact, at least a portion of the clusters forming conductive pathways between adjacent bundles,
wherein the carbon nanotube network and the conductive pathways define a percolative conductive network on the substrate.

2. The conductive network of claim 1 wherein the bundles comprise a length-to-width aspect ratio of from about 100 to about 10,000.

3. The conductive network of claim 1, wherein the conductive particles comprise a particle size of between about 1 nm and 100 nm.

4. The conductive network of claim 1, wherein a weight ratio of carbon nanotubes to conductive particles is between about 1:2,000 and 2,000:1.

5. The conductive network of claim 1, wherein the substrate comprises a transparent substrate.

6. The conductive network of claim 5, wherein the transparent substrate is one of glass and a polymer.

7. The conductive network of claim 1 comprising a transmittance of at least about 80% at a wavelength between approximately 390 nm and approximately 750 nm.

8. The conductive network of claim 1, wherein the conductive particles comprise indium-tin oxide.

9. The conductive network of claim 1, wherein the carbon nanotubes include a dopant for enhanced electrical conductivity.

10. The conductive network of claim 9, wherein the dopant comprises an acid.

11. A conductive polymer composite comprising:
a polymer matrix; bundles of carbon nanotubes dispersed in the polymer matrix, a plurality of the bundles including one or more points of contact with at least one adjacent bundle to form a carbon nanotube network through the polymer matrix; and
clusters of conductive particles dispersed in the polymer matrix and separating the bundles of carbon nanotubes in regions between the points of contact, at least a portion of the clusters forming conductive pathways between adjacent bundles,
wherein the carbon nanotube network and the conductive pathways define a percolative conductive network through the polymer matrix.

12. The conductive polymer composite of claim 11, wherein the bundles comprise a length-to-width aspect ratio of from about 100 to about 10,000.

13. The conductive polymer composite of claim 11, wherein the carbon nanotubes are present in the polymer matrix at a concentration of between about 0.0001 wt. % and 10 wt. %.

14. The conductive polymer composite of claim 11, wherein a weight ratio of carbon nanotubes to conductive particles in the polymer matrix is between about 1:2,000 and 2,000:1.

15. The conductive polymer composite of claim 11, wherein the polymer matrix comprises a polymer selected from the group consisting of polystyrene, polycarbonate, and polymethylmethacrylate.

16. The conductive polymer composite of claim 11, wherein the conductive particles comprise a particle size of between about 1 nm and 100 nm.

17. The conductive polymer composite of claim 11, wherein the conductive particles comprise indium-tin oxide.

18. The conductive polymer composite of claim 11 comprising a transmittance of at least about 80% at a wavelength between about 390 nm and about 750 nm.

19. The conductive polymer composite of claim 11, wherein the polymer matrix comprises compressed polymeric beads and wherein the bundles of carbon nanotubes and the clusters of conductive particles are localized at interfaces between adjacent compressed polymeric beads.

20. The conductive polymer composite of claim 11, wherein the carbon nanotubes include a dopant for enhanced electrical conductivity.
